(19) United States
(12) Patent Application Publication
(10) Pub. No.: US 2026/0190314 A1
(43) Pub. Date: Jul. 2, 2026

(54) INTEGRATED CIRCUIT

(71) Applicant: Taiwan Semiconductor Manufacturing Company, Ltd., Hsinchu (TW)

(72) Inventor: Jhon Jhy Liaw, Hsinchu County (TW)

(73) Assignee: Taiwan Semiconductor Manufacturing Company, Ltd., Hsinchu (TW)

(21) Appl. No.: 19/001,560

(22) Filed: Dec. 26, 2024

(51) Int. Cl. H10B 10/00

(52) U.S. Cl. CPC H10B 10/125

(57) ABSTRACT

An integrated circuit is provided. The integrated circuit has memory cells, each including an inverter, formed on a frontside of a semiconductor substrate, and including two pull-down transistors connected in parallel and a pull-up transistor connected to the pull-down transistors; a lateral contact, formed over the inverter at the frontside of the semiconductor substrate, and laterally extending to land on a source/drain terminal of one of the pull-down transistors and a source/drain terminal of the other of the pull-down transistors; and a power rail, extending at a backside of the semiconductor substrate and coupled to a reference voltage. The source/drain terminals of the pull-down transistors bridged by the lateral contact are further connected to the power rail.

### BACKGROUND

At advanced technology node, embedded static random access memory (SRAM) is comprehensively used as cache memory in high speed communication, image processing, system-on-chip (SOC) and similar products. As compared to single port SRAM, dual port SRAM allows parallel operation and thus can be operated with greater bandwidth.

However, the dual port SRAM is more complicated in routing than the single port SRAM. Conventionally, the dual port SRAM is limited to being routed at wafer frontside. With aggressive scaling, line width and line spacing of the wirings for routing the dual port SRAM are significantly reduced. As a consequence, resistance along the wirings and parasitic capacitance between the wirings are adversely increased. This will slow down the dual port SRAM, or otherwise hold back the scaling process. A solution for improving routing for the dual port SRAM while allowing further scaling without slowing down the dual port SRAM is eager to be found in the art.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of a dual port SRAM cell, according to some embodiments of the present disclosure.

FIG. 2 is a block diagram illustrating a dual port SRAM including a memory array having a plurality of the cells shown in FIG. 1 and driving circuits for operating the memory array, according to some embodiments of the present disclosure.

FIG. 3 includes schematic plan views showing layout design of the dual port SRAM cell at wafer frontside and wafer backside, according to some embodiments of the present disclosure.

FIG. 4 schematically illustrates an overview of a semiconductor chip containing the dual port SRAM, according to some embodiments of the present disclosure.

FIG. 5A is a schematic plan view showing layout of 4 adjacent dual port SRAM cells at wafer frontside, according to some embodiments of the present disclosure.

FIG. 5B is a schematic plan view showing layout of 4 adjacent dual port SRAM cells at wafer backside, according to some embodiments of the present disclosure.

FIG. 6A through FIG. 6G are schematic cross-sectional views illustrating cross-sections along a few components in the dual port SRAM cell, according to some embodiments of the present disclosure.

FIG. 7 provides schematic plan views showing layout design of a dual port SRAM cell at wafer frontside and wafer backside, according to some other embodiments of the present disclosure.

FIG. 8 provides schematic plan views showing layout design of a dual port SRAM cell at wafer frontside and wafer backside, according to yet other embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a solution for improving routing for a dual port SRAM while allowing further scaling without slowing down the dual port SRAM.

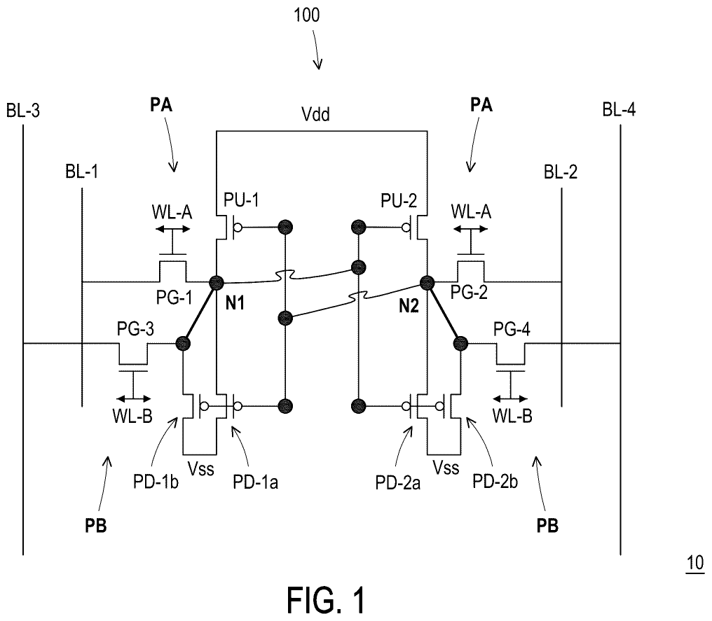

FIG. 1 is a circuit diagram of a cell 10 in the dual port SRAM (or referred to as a dual port SRAM cell 10), according to some embodiments of the present disclosure.

The dual port SRAM cell 10 includes a latch circuit 100 for storing complementary data at nodes N1, N2. A pass-gate transistor PG-1 coupled to the node N1 and a pass-gate transistor PG-2 coupled to the node N2 control a first port PA of the dual port SRAM cell 10, whereas a pass-gate transistor PG3 also coupled to the node N1 as well as a pass-gate transistor PG4 also coupled to the node N2 control a second port PB of the dual port SRAM cell 10. Write operations can be performed through the first port PA or the second port PB. Similarly, data stored at the nodes N1, N2 can be read from the first port PA or the second port PB.

Specifically, a first word line WL-A is coupled to gate terminals of the pass-gate transistors PG-1, PG-2, to control switching of the pass-gate transistors PG-1, PG-2, thus control access of the first port PA. The pass-gate transistor PG-1 is coupled to the node N1 via one of its source/drain terminals, whereas the other source/drain terminal of the pass-gate transistor PG-1 is coupled to a first bit line BL-1. Similarly, the pass-gate transistor PG-2 is coupled to the node N2 via one of its source/drain terminals, whereas the other source/drain terminal of the pass-gate transistor PG-2 is coupled to a second bit line BL-2.

During a write operation through the first port PA, data (e.g., complementary data) is provided to the first and second bit lines BL-1, BL-2 and written to the nodes N1, N2 through the pass-gate transistors PG-1, PG-2. During a read operation through the first port PA, the first and second bit lines BL-1, BL-2 are pre-charged. When the pass-gate transistors PG-1, PG-2 are switched on, one of the first and second bit lines BL-1, BL-2 would be pulled down by the logic low data stored at the node N1 or the node N2. By sensing voltage variation on the first and second bit lines BL-1, BL-2, data stored at the nodes N1, N2 can be identified.

Such configuration is also applied to the second port PB. Specifically, a second word line WL-B is coupled to gate terminals of the pass-gate transistors PG-3, PG-4, to control switching of the pass-gate transistors PG-3, PG-4, thus control access of the second port PB. The pass-gate transistor PG-3 is coupled to the node N1 via one of its source/drain terminals, whereas the other source/drain terminal of the pass-gate transistor PG-3 is coupled to a third bit line BL-3. Similarly, the pass-gate transistor PG-4 is coupled to the node N2 via one of its source/drain terminals, whereas the other source/drain terminal of the pass-gate transistor PG-4 is coupled to a fourth bit line BL-4.

During a write operation through the second port PB, data (e.g., complementary data) is provided to the third and fourth bit lines BL-3, BL-4 and written to the nodes N1, N2 through the pass-gate transistors PG-3, PG-4. During a read operation through the second port PB, the third and fourth bit lines BL-3, BL-4 are pre-charged. When the pass-gate transistors PG-3, PG-4 are switched on, one of the third and fourth bit lines BL-3, BL-4 would be pulled down by the logic low data stored at the node N1 or the node N2. By sensing voltage variation on the third and fourth bit lines BL-3, BL-4, data stored at the nodes N1, N2 can be identified.

The latch circuit 100 includes a first pull-up transistor PU-1 and a first pull-down transistor PD-1a with a common source/drain terminal defining the node N1, which is accessible to the first port PA as being coupled to a source/drain terminal of the pass-gate transistor PG-1, and accessible to the second port PB as being coupled to a source/drain terminal of the pass-gate transistor PG3. The other source/drain terminal of the first pull-up transistor PU-1 is connected to a power supply voltage Vdd, while the other source/drain terminal of the first pull-down transistor PD-1a is connected to a reference voltage Vss. In addition, gate terminals of the first pull-up transistor PU-1 and the first pull-down transistor PD-1a are connected to each other.

The first pull-up transistor PU-1 and the first pull-down transistor PD-1a are connected to form a first inverter. According to some embodiments, the first inverter further includes an additional pull-down transistor PD-1b connected in parallel with the first pull-down transistor PD-1a. Specifically, a source/drain terminal of the additional pull-down transistor PD-1b is coupled to the node N1, and the other source/drain terminal of the additional pull-down transistor PD-1b is coupled to the reference voltage Vss. In addition, a gate terminal of the additional pull-down transistor PD-1b is coupled to the gate terminals of the first pull-up transistor PU-1 and the first pull-down transistor PD-1a. The first pull-down transistor PD-1a and the additional pull-down transistor PD-1b are connected to enhance voltage pull-down at the node N1, for preventing read disturb.

The latch circuit 100 also includes a second pull-up transistor PU-2 and a second pull-down transistor PD-2a with a common source/drain terminal defining the node N2, which is accessible to the first port PA as being coupled to a source/drain terminal of the pass-gate transistor PG-2, and accessible to the second port PB as being coupled to a source/drain terminal of the pass-gate transistor PG4. The other source/drain terminal of the second pull-up transistor PU-2 is connected to the power supply voltage Vdd, while the other source/drain terminal of the second pull-down transistor PD-2a is connected to the reference voltage Vss. In addition, gate terminals of the second pull-up transistor PU-2 and the second pull-down transistor PD-2a are connected to each other.

The second pull-up transistor PU-2 and the second pull-down transistor PD-2a are connected to form a second inverter cross-coupled to the first inverter. The node N1 as an output of the first inverter is coupled to the connected gate terminals of the second pull-up transistor PU-2 and the second pull-down transistor PD-2a as an input of the second inverter, and the node N2 as an output of the second inverter is coupled to the connected gate terminals of the first pull-up transistor PU-1 and the first pull-down transistor PD-1a as an input of the first inverter.

In those embodiments where the first inverter further includes the additional pull-down transistor PD-1b, the input of the first inverter is also coupled to the gate terminal of the additional pull-down transistor PD-1b, and the output of the first inverter is also coupled to one of the source/drain terminals of the additional pull-down transistor PD-1b. Further, the second inverter may also include an additional pull-down transistor PD-2b connected in parallel with the second pull-down transistor PD-2a. Specifically, a source/drain terminal of the additional pull-down transistor PD-2b is coupled to the node N2 (as an output of the second inverter), and the other source/drain terminal of the additional pull-down transistor PD-2b is coupled to the reference voltage Vss. In addition, a gate terminal of the additional pull-down transistor PD-2b is coupled to the gate terminals of the second pull-up transistor PU-2 and the second pull-down transistor PD-2a, which define the input of the second inverter. The second pull-down transistor PD-2a and the additional pull-down transistor PD-2b are connected to enhance voltage pull-down at the node N2, for preventing read disturb.

The dual port SRAM includes more of the cells 10, and also includes driving circuits for operating the cells 10.

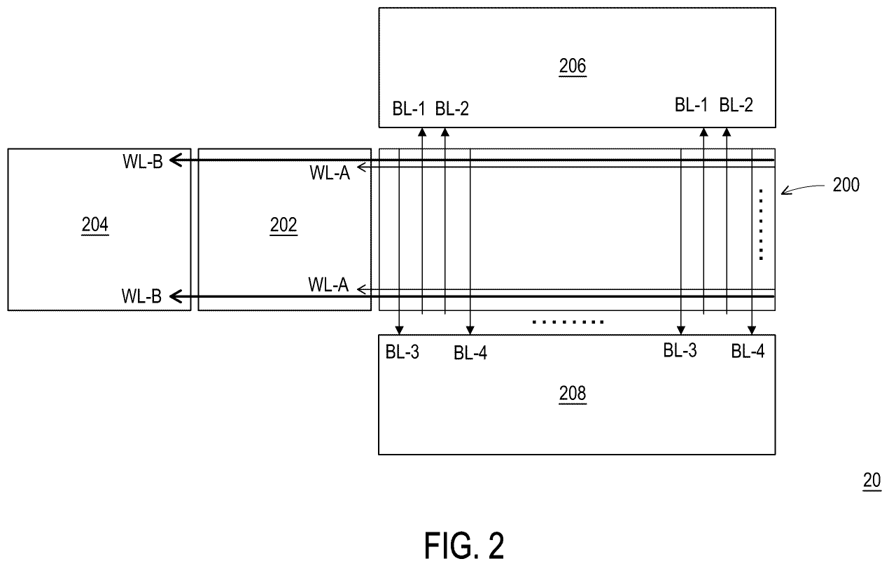

FIG. 2 is a block diagram illustrating a dual port SRAM 20 including a memory array 200 having a plurality of the cells 10 and driving circuits for operating the memory array 200, according to some embodiments of the present disclosure.

As described, each of the cells 10 can be accessed via two ports (i.e., the ports PA, PB), and coupled to a pair of word lines (i.e., the word lines WL-A, WL-B). A plurality of the word lines WL-A are respectively connected a row of the cells 100, and control access to these cells 10 via their ports PA. Similarly, a plurality of the word lines WL-B are respectively connected to a row of the cells 10, while controlling access to these cells 10 via their ports PB. Different word line drivers are used for controlling the word lines WL-A and the word lines WL-B. As an example, the word lines WL-A extend to a word line driver 202, whereas the word lines WL-B extend to a word line driver 204.

The two ports PA, PB of each cell 10 are respectively coupled to a pair of bit lines (i.e., the bit lines BL-1, BL-2 or the bit lines BL-3, BL-4). Multiple pairs of the bit lines BL-1, BL-2 are respectively connected to the ports PA of a column of the cells 10, while multiple pairs of the bit lines BL-3, BL-4 are respectively connected to the ports PB of a column of the cells 10. Different bit line drivers each including, for example, multiplexer and sense amplifier are used for controlling the bit lines BL-1, BL-2 and the bit lines BL-3, BL-4. As an example, the bit lines BL-1, BL-2 extend to and are controlled by a bit line driver 206, whereas the bit lines BL-3, BL-4 extend to and are controlled by a bit line driver 208.

As compared to a single port SRAM cell, a double amount of signal lines are connected to a dual port SRAM cell, and each dual port SRAM cell requires more complicated routing. Along with continuous scaling, wafer frontside becomes very crowded for routing the dual port SRAM cells, which adversely increase resistance along the wirings in the routing as well as parasitic capacitance between the wirings, and slows down the dual port SRAM. As a solution provided in the present disclosure, part of the routing for each dual port SRAM cell 10 is moved to wafer backside.

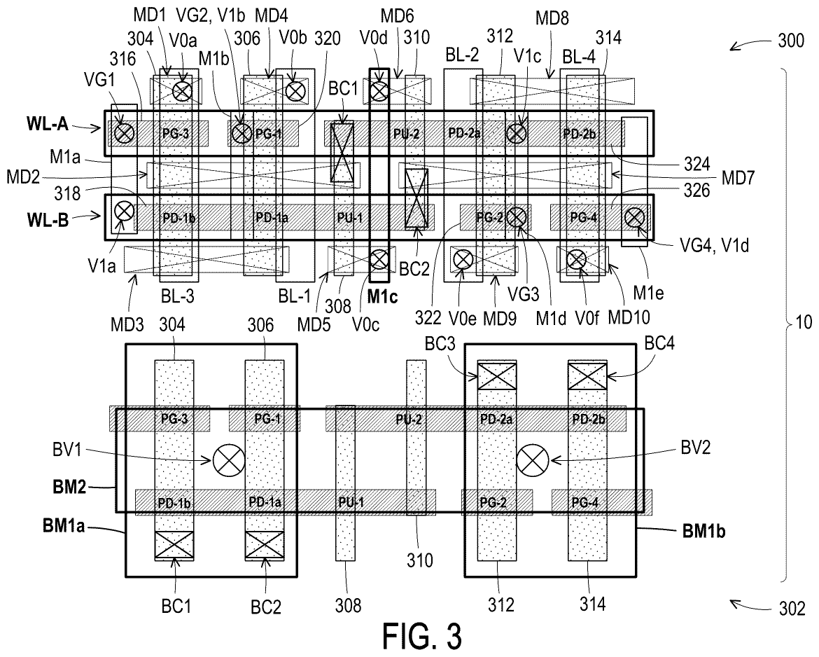

FIG. 3 includes schematic plan views showing layout design of the dual port SRAM cell 10 at wafer frontside and wafer backside, according to some embodiments of the present disclosure.

Specifically, a plan view 300 schematically illustrates layout patterns of the dual port SRAM cell 10 at a frontside of a semiconductor substrate (or referred to as a wafer), whereas a plan view 302 shows layout patterns of the dual port SRAM cell 10 at a backside of the semiconductor substrate. Nonetheless, active structures 304, 306, 308, 310, 312, 314 and gate patterns 316, 318, 320, 322, 324, 326 formed on the frontside of the semiconductor substrate are also shown in the backside plan view 302, to specify relationship between the layout patterns at the backside of the semiconductor substrate and the layout patterns at the frontside of the semiconductor substrate.

The active structures 304, 306, 312, 314 are formed on P wells (not shown) in the semiconductor substrate, whereas the active structures 308, 310 are formed on an N well (also not shown) positioned between the P wells in the semiconductor substrate. According to some embodiments, the active structures 304, 306, 308, 310, 312, 314 respectively include channel structures stacked on the semiconductor substrate and vertically spaced apart from one another. In alternative embodiments, the active structures 304, 306, 308, 310, 312, 314 are respectively provided by a semiconductor fin structure. In other embodiments, the active structures 304, 306, 308, 310, 312, 314 are shallow regions of the semiconductor substrate.

From the left side of the plan views 300, 302, the gate structure 316 crosses over and covers the active structures 304, such that the pass-gate transistor PG-3 is defined at the intersection of the active structure 304 and the gate structure 316. The active structure 304 further extends, and the gate structure 318 below the gate structure 316 (as shown in the plan views 300, 302) crosses over and covers the active structure 304 as well. The additional pull-down transistor PD-1b is defined at the intersection of the active structure 304 and the gate structure 318.

The gate structure 318 further extends away from the left side of the plan views 300, 302, to cross over and cover the active structure 306 next to the active structure 304. The first pull-down transistor PD-1a is defined at the intersection of the active structure 306 and the gate structure 318. In addition, the active structure 306 extends, such that the gate structure 320 above the gate structure 318 (as shown in the plan views 300, 302) also crosses over and covers the active structure 306, and the pass-gate transistor PG-1 is defined at the intersection of the active structure 306 and the gate structure 320.

In addition to crossing over a left one of the P wells (where the active structures 304, 306 sit), the gate structure 318 further extends over the N well between the P wells. The active structure 308 next to the active structure 306 is crossed over and covered by the gate structure 318, and the first pull-up transistor PU-1 is defined at the intersection of the active structure 308 and the gate structure 318.

The layout patterns of the active structures 304, 306, 308, 310, 312, 314 and the gate structures 316, 318, 320, 322, 324, 326 may be designed with two-fold symmetry. Specifically, the active structures 304, 306, 308 may match the active structures 314, 312, 310 if they are rotated by 180 degrees with respect to a central axis of the plan view 300/302. Similarly, the gate structures 316, 318, 320 may match the gate structures 326, 324, 322 if they are rotated by 180 degrees with respect to the central axis of the plan view 300/302.

From the right side of the plan views 300, 302, the gate structure 326 crosses over and covers the active structures 314, such that the pass-gate transistor PG-4 is defined at the intersection of the active structure 314 and the gate structure 326. The active structure 314 further extends, and the gate structure 324 above the gate structure 316 (as shown in the plan views 300, 302) crosses over and covers the active structure 314 as well. The additional pull-down transistor PD-2b is defined at the intersection of the active structure 314 and the gate structure 324.

The gate structure 324 further extends away from the right side of the plan views 300, 302, to cross over and cover the active structure 312 next to the active structure 314. The second pull-down transistor PD-2a is defined at the intersection of the active structure 312 and the gate structure 324. In addition, the active structure 312 extends, such that the gate structure 322 below the gate structure 324 (as shown in the plan views 300, 302) also crosses over and covers the active structure 312, and the pass-gate transistor PG-2 is defined at the intersection of the active structure 312 and the gate structure 322.

In addition to crossing over a right one of the P wells (where the active structures 314, 312 sit), the gate structure 324 further extends over the N well between the P wells. The active structure 310 next to the active structure 312 is crossed over and covered by the gate structure 324, and the second pull-up transistor PU-2 is defined at the intersection of the active structure 310 and the gate structure 324. As described, the active structures 314, 312, 310 and the gate structures 326, 324, 322 as a first half of a two-fold symmetric pattern are designed to match the active structures 304, 306, 308 and the gate structures 316, 318, 320 as a second half of the two-fold symmetric pattern, if being rotated by 180 degrees with respect to the central axis of the two-fold symmetric pattern.

To rout the pass-gate transistor PG-3 defined at the intersection of the active structure 304 and the gate structure 316, a gate via VG1 is disposed on the gate structure 316, and connects the gate structure 316 to a landing pattern M1a that extends to be overlapped by the word line WL-B laterally offset from the gate structure 316. A via V1a may be used for connecting the landing pattern M1a to the word line WL-B. In addition, a lateral contact MD1 is disposed on one of the source/drain terminal of the pass-gate transistor PG-3, and a via V0a is used for connecting the lateral contact MD1 to the bit line BL-3.

The other source/drain terminal of the pass-gate transistor PG-3 is shared with the additional pull-down transistor PD-1b disposed along the same active structure 304, and is routed by a lateral contact MD2. Specifically, the lateral contact MD2 is part of the node N2, and connects the common source/drain terminal of the pass-gate transistor PG3 and the additional pull-down transistor PD-1b to the common source/drain terminal of the pass-gate transistor PG-1, the first pull-down transistor PD-1a and the first pull-up transistor PU1. In addition, the other source/drain terminal of the additional pull-down transistor PD-1b is connected to the other source/drain terminal of the first pull-down transistor PD-1a via a lateral contact MD3 that extends across the active structure 304 and the active structure 306. As will be further described, the lateral contact MD3 is coupled to the reference voltage Vss provided from the backside of the semiconductor substrate.

A lateral contact MD4 is placed on the other source/drain terminal of the pass-gate transistor PG-1, and is connected to the overlying bit line BL-1 through a via V0b. In addition, the gate terminal of the pass-gate transistor PG-1 is connected to an overlying landing pattern M1b by a gate via VG2, and the landing pattern M1b may be connected to the overlying word line WL-A by a via V1b overlapping the gate via VG2.

As one of the source/drain terminals of the first pull-up transistor PU-1 is routed by the lateral contact MD2 and the gate terminal of the first pull-up transistor PU-1 is connected to the gate terminals of the first pull down transistor PD-1a and the additional pull-down transistor PD-1b along the gate structure 322, the other source/drain terminal of the first pull-up transistor PU-1 is routed via a lateral contact MD5. In some embodiments, the lateral contact MD5 is connected to an interconnection line M1c through a via V0c. As will be further described, the interconnection line M1c is configured to be provided with the power supply voltage Vdd from wafer backside.

The lateral contact MD2 connecting the common source/drain terminal of the pass-gate transistor PG3 and the additional pull-down transistor PD-1b with the common source/drain terminal of the pass-gate transistor PG-1, the first pull-down transistor PD-1a and the first pull-up transistor PU-1 is further connected to the gate terminal of the second pull-up transistor PU-2 (provided by the gate structure 324) via a butted contact BC1. The butted contact BC1 laterally extends to land on both of the lateral contact MD2 and the gate structure 324 providing the gate terminal for the second pull-up transistor PU2.

As similar to the first pull-up transistor PU-1, the second pull-up transistor PU-2 has a source/drain terminal connected to the overlying interconnection line M1c provided with the power supply voltage Vdd. A lateral contact MD6 lying on the active structure 310 and extending to be overlapped with the interconnection line M1c as well as a via V0d may be used for implementing such connection. On the other hand, the other source/drain terminal of the second pull-up transistor PU-2 is connected to the common source/drain terminal of the pass-gate transistor PG-2 and the second pull-down transistor PD-2a as well as the common source/drain terminal of the pass-gate transistor PG-4 and the additional pull-down transistor PD-2b via a lateral contact MD7. Further, the lateral contact MD7 as part of the node N2 is connected to the gate terminals of the first pull-up transistor PU1, the first pull-down transistor PD-1a and the additional pull-down transistor PD-1b via another butted contact BC2. Specifically, the butted contact BC2 lands on both of the lateral contact MD6 and the gate structure 322 providing the gate terminals for the first pull-up transistor PU1, the first pull-down transistor PD-1a and the additional pull-down transistor PD-1b.

The second pull-down transistor PD-2a and the additional pull-down transistor PD-2b are connected in parallel. Specifically, the second pull-down transistor PD-2a and the additional pull-down transistor PD-2b share the gate structure 324. A source/drain terminal of the second pull-up transistor PD-2a (the one shared with the pass-gate transistor PG-2) is linked with a source/drain terminal of the additional pull-down transistor PD-2b (the one shared with the pass-gate transistor PG-4) via the lateral contact MD7. Further, the other source/drain terminal of the second pull-up transistor PD-2a is connected with the other source/drain terminal of the additional pull-down transistor PD-2b via a lateral contact MD8 extending across the active structure 312 and the active structure 314. As will be described, the lateral contact MD8 is coupled to the reference voltage Vss provided from the backside of the semiconductor substrate.

The active structure 312 intersecting the gate structure 324 to define the second pull-down transistor PD-2a further extends to be intersected with the gate structure 322 below the gate structure 324 (as shown in the plan views 300, 302) as well, and the pass-gate transistor PG-2 is defined at the intersection of the active structure 312 and the gate structure 322. While a source/drain terminal of the pass-gate transistor PG-2 is routed via the lateral contact MD7, the other source/drain terminal of the pass-gate transistor PG-2 is connected to the overlying bit line BL-2 via a lateral contact MD9 and a via V0e. The lateral contact MD9 lies on the active structure 312 and may be laterally extend to be overlapped by the bit line BL-2, and the via V0e connects the lateral contact MD9 to the overlying bit line BL-2. Further, the gate structure 322 providing the gate terminal of the pass-gate transistor PG-2 is connected to an overlying landing pattern M1d via a gate via VG3, and the landing pattern M1d extends to be overlapped with the word line WL-A laterally offset from the gate structure 322. A via V1c may be used for connecting the landing pattern M1d to the word line WL-A.

The active structure 314 intersecting the gate structure 324 to define the additional pull-down transistor PD-2b further extends to be intersected with the gate structure 326 below the gate structure 324 (as shown in the plan views 300, 302), and the pass-gate transistor PG-4 is defined at the intersection of the active structure 314 and the gate structure 326. While a source/drain terminal of the pass-gate transistor PG-4 is routed via the lateral contact MD7, the other source/drain terminal of the pass-gate transistor PG-4 is connected to the overlying bit line BL-4 via a lateral contact MD10 and a via V0f. The lateral contact MD10 lies on the active structure 314 and may be overlapped by the bit line BL-4, and the via V0f connects the lateral contact MD10 to the overlying bit line BL-4. Further, the gate structure 326 providing the gate terminal of the pass-gate transistor PG-4 is connected to an overlying landing pattern M1e via a gate via VG4, and the landing pattern M13 is overlapped with the word line WL-B. A via V1d may be used for connecting the landing pattern M1e to the word line WL-B.

While the interconnection of the transistors is implemented at the frontside of the semiconductor substrate, the transistors are powered from the backside of the semiconductor substrate. In addition to being connected with each other via the lateral contact MD3 at the frontside of the semiconductor substrate, one of the source/drain terminals of the first pull-down transistor PD-1a and one of the source/drain terminals of the additional pull-down transistor PD-1b are routed to a backside power rail BM1a via backside contacts BC1, BC2. Specifically, the backside contact BC1 extends through the active structure 304 from the backside of the semiconductor substrate to establish contact with a source/drain structure, and is overlapped with the lateral contact MD3 in contact with the source/drain structure from a top side of the source/drain structure. Also, the backside contact BC2 extends through the active structure 306 from the backside of the semiconductor substrate to establish contact with a source/drain structure, and is overlapped with the lateral contact MD3 in contact with the source/drain structure from a top side of the source/drain structure. The backside power rail BM1a is formed on the backside contacts BC1, BC2 when the backside of the semiconductor substrate faces upwardly, and is coupled to the reference voltage Vss provided through backside routing layers further formed on the backside power rail BM1a (including the backside power rail BM2 to be described in further details).

Similarly, one of the source/drain terminals of the second pull-down transistor PD-2a and one of the source/drain terminals of the additional pull-down transistor PD-2b that are connected via the lateral contact MD8 at the frontside of the semiconductor substrate are further connected to a backside power rail BM1b via backside contacts BC3, BC4. Specifically, the backside contact BC3 extends through the active structure 312 from the backside of the semiconductor substrate to establish contact with a source/drain structure, and is overlapped with the lateral contact MD8 in contact with the source/drain structure from a top side of the source/drain structure. Also, the backside contact BC4 extends through the active structure 314 to establish contact with a source/drain structure, and is overlapped with the lateral contact MD8 in contact with the source/drain structure from a top side of the source/drain structure. The backside power rail BM1b is formed on the backside contacts BC3, BC4 when the backside of the semiconductor substrate faces upwardly, and is coupled to the reference voltage Vss provided through backside routing layers further formed on the backside power rail BM1a (including the backside power rail BM2 to be described in further details).

As compared to the frontside of the semiconductor substrate, the backside of the semiconductor substrate is much less crowded with wirings, and the backside power rails BM1a, BM1b can widely span to reduce resistance across the backside power rails BM1a BM1b. In some embodiments, the backside power rail BM1a is overlapped with the P well where the active structures 304, 306 sit, and the backside power rail BM1b is overlapped with the P well where the active structures 312, 314 sit. In these embodiments, the active structures 304, 306 may be entirely overlapped with the backside power rail BM1a, and the active structures 312, 314 may be entirely overlapped with the backside power rail BM1b. In addition, a width of the backside power rail BM1a along the direction which the gate structures 316, 318, 320, 322, 324, 326 extend may be greater than a total width of the active structures 304, 306 along the same direction, and the backside power rail BM1a may extend along the P well and the active structures 304, 306. Also, a width of the backside power rail BM1b along the direction which the gate structures 316, 318, 320, 322, 324, 326 extend is greater than a total width of the active structures 312, 314 along the same direction, and the backside power rail BM1b may extend along the P well and the active structures 312, 314.

As one of the source/drain terminals of the first pull-down transistor PD-1a and one of the source/drain terminals of the additional pull-down transistor PD-1b are bridged by both the lateral contact MD3 and the backside power rail BM1a, the lateral contact MD3 is connected in parallel with the backside power rail BM1a. Similarly, the lateral contact MD8 is connected in parallel with the backside power rail BM1b. Based on such configuration, an equivalent resistance of the lateral contact MD3 and the backside power rail BM1a connected in parallel would be lower than a resistance of the backside power rail BM1a itself, and an equivalent resistance of the lateral contact MD8 and the backside power rail BM1b connected in parallel would be lower than a resistance of the backside power rail BM1b itself. Thereby, by further disposing the lateral contacts MD3, MD8, resistance along the paths for providing the reference voltage Vss can be lowered.

Furthermore, even if one of the backside contacts BC1, BC2 fails to connect the corresponding source/drain terminal to the backside power rail BM1a, such source/drain terminal can be connected to the backside power rail BM1a via the lateral contact MD3 and the other backside contact BC1/BC2. Similarly, even if one of the backside contacts BC3, BC4 fails to connect the corresponding source/drain terminal to the backside power rail BM1b, such source/drain terminal can be connected to the backside power rail BM1b via the lateral contact MD8 and the other backside contact BC3/BC4. Accordingly, tolerance of overlay between the backside contacts BC1, BC2 and the active structures 304, 306 as well as overlay between the backside contacts BC3, BC4 and the active structures 312, 314 are improved.

As described, the backside power rails BM1a, BM1b can be further routed. Additional backside power rails may include a backside power rail BM2 stacked on and intersecting the backside power rails BM1a, BM1b. Backside vias BV1, BV2 may be used for connecting the backside power rails BM1a, BM1b to the backside power rail BM2. The backside via BV1 extends from the backside power rail BM1a to the backside power rail BM2, whereas the backside via BV2 extends from the backside power rail BM1b to the backside power rail BM2. As similar to the design of the backside power rails BM1a, BM1b, the backside power rail BM2 can be formed with a large line width. In some embodiments, the backside power rail BM2 extends along the same direction as the gate structures 316, 318, 320, 322, 324, 326, and widely spans such that all of the gate structures 316, 318, 320, 322, 324, 326 are overlapped with the backside power rail BM2.

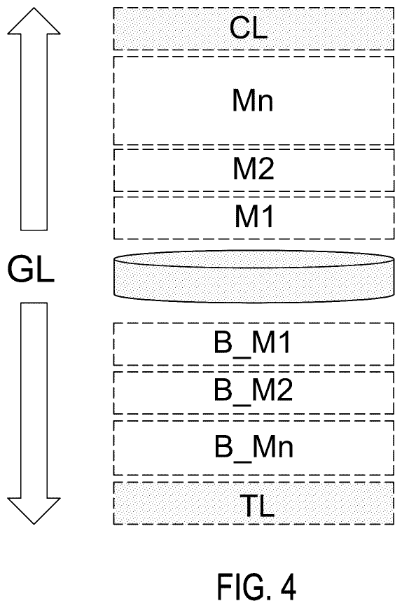

Although not shown, there may be one or more backside power rail(s) stacked on the backside power rail BM2. FIG. 4 schematically illustrates an overview of a semiconductor chip 40 containing the dual port SRAM, according to some embodiments of the present disclosure.

The device level GL contains the pass-gate transistors PG-1, PG-2, PG-3, PG-4, the pull-down transistors PD-1a, PD-1b, PD-2a, PD-2b and the pull-up transistors PU-1, PU-2 defined by the active structures 304, 306, 308, 310, 312, 314 and the gate structures 316, 318, 320, 322, 324, 326. In addition, the device level GL may also contain the vias V0a, V0b, V0c, V0d, V0e, V0f, VG1, VG2, VG3, VG4 as well as the lateral contacts MD1, MD2, MD3, MD4, MD5, MD6, MD7, MD8, MD9, MD10.

A plurality of frontside metallization tiers are stacked on the frontside of the semiconductor substrate to interconnect the pass-gate transistors PG-1, PG-2, PG-3, PG-4, the pull-down transistors PD-1a, PD-1b, PD-2a, PD-2b and the pull-up transistors PU-1, PU-2. These frontside metallization tiers include a first metallization tier M1, a second metallization tier M2 over the first metallization tier M1, and higher metallization tier(s) Mn on the second metallization tier M2. The first metallization tier M1 contains the landing patterns M1a, M1b, M1d, M1e, the bit lines BL-1, BL-2, BL-3, BL-4 and the interconnection line M1c. In some embodiments, the second metallization tier M2 contains the vias V1a, V1b, V1c, V1d and the word lines WL-A, WL-B. The higher metallization tier(s) Mn may include more routing lines and vias.

A few dielectric layers (not shown) may be formed on top of the metallization tier(s) Mn. Further, a cap layer CL may be disposed on these dielectric layers, and defines a frontside of the semiconductor chip 40. The cap layer CL can be functioned as a support layer when the semiconductor substrate is subjected to backside processing. In some embodiments, the cap layer CL is a semiconductor layer, such as a silicon layer. Further, in some embodiments, the semiconductor chip 40 is powered solely from backside, and there is no electrical connectors disposed on the cap layer CL.

When the device level GL is covered by the frontside metallization tiers M1, M2, Mn, the resulted structure may be flipped over, with the cap layer CL supports from below. Further, the semiconductor substrate may be subjected to backside processing, for forming multiple backside metallization tiers. These backside metallization tiers may include a first backside metallization tier B_M1, a second backside metallization tier B_M2 over the first backside metallization tier B_M1, and higher backside metallization tier(s) B_Mn on the second backside metallization tier B_M2. The first backside metallization tier B_M1 may contain the backside contacts BC1, BC2, BC3, BC4 and the backside power rails BM1a, BM1b. In addition, the second backside metallization tier B_M2 may include the backside power rail BM2 and the backside vias BV1, BV2, and the higher backside metallization tier(s) B_Mn may include more backside power rails.

A terminal layer TL is formed on the highest backside metallization tier B_Mn, for providing power source to the backside power rails, and also providing input/output (I/O) terminals for the semiconductor chip 40. Since the power rails are formed at wafer backside rather than wafer frontside, the power supply voltage Vdd and the reference voltage Vss came from the terminal layer TL at wafer backside can be supplied to the power rails by shorter paths. Accordingly, voltage drop along the paths can be minimized. Electrical connectors (not shown) are formed in the terminal layer TL and coupled to external power source. In some embodiments, the electrical connectors are electrical bumps. In alternative embodiments, the electrical connector are bonding pads.

As described, the backside power rails (including the backside power rails BM1a, BM1b, BM2), the backside vias (including the backside vias BV1, BV2) and the backside contacts BC1, BC2, BC3, BC4 are configured to provide the reference voltage Vss to the pull-down transistors PD-1a, PD-1b, PD-2a, PD-2b. Although not shown, additional backside routings are formed to provide the power supply voltage Vdd to the pull-up transistors PU-1, PU-2. In some embodiments, these additional backside routings coupled to the power supply voltage Vdd may be connected to the interconnection line M1c at the frontside of the semiconductor substrate via through substrate via (not shown) extending through the semiconductor substrate. In these embodiments, the interconnection line M1c may be functioned as a frontside power rail for powering the pull-up transistors PU-1, PU-2.

To reduce total area, the active structures 304, 306, 312, 314, the gate structure 316, 326, the word lines WL-A, WL-B, the bit lines BL-1, BL-2, BL-3, BL-4 and the interconnection line M1c can extend through cell boundary and can be shared by adjacent cells. In addition, the lateral contacts placed near the cell boundary can further extend through the cell boundary, and can be shared by adjacent cells as well.

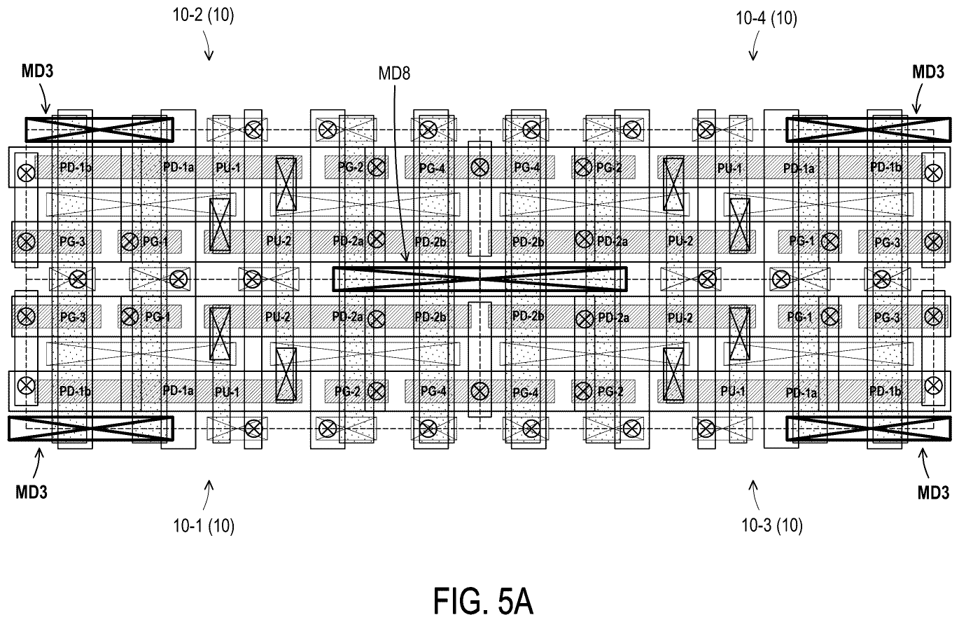

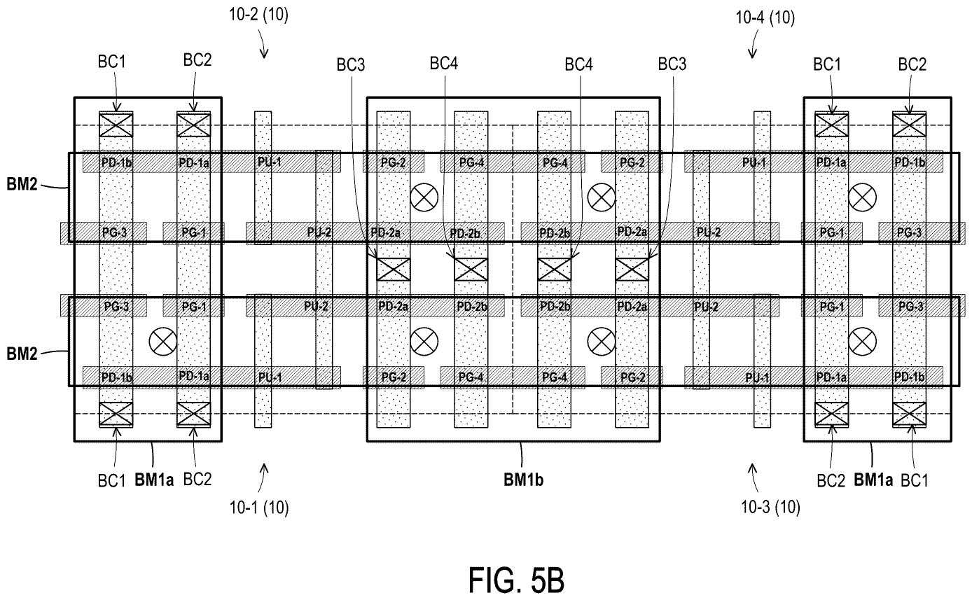

FIG. 5A is a schematic plan view showing layout of 4 adjacent dual port SRAM cells 10 at wafer frontside, according to some embodiments of the present disclosure.

These dual port SRAM cells 10 include a first dual port SRAM cell 10-1, a second dual port SRAM cell 10-2, a third dual port SRAM cell 10-3 and a fourth dual port SRAM cell 10-4. The first and second dual port SRAM cells 10-1, 10-2 are arranged along shared active structures, bit lines and interconnection line, and abut with each other. Similarly, the third and fourth dual port SRAM cells 10-3, 10-4 are arranged along shared active structures, bit lines and interconnection line, and abut with each other. Further, the first and second dual port SRAM cells 10-1, 10-2 abut the third and fourth dual port SRAM cells 10-3, 10-4 side-by-side.

According to some embodiments, the first and second dual port SRAM cells 10-1, 10-2 are in mirror symmetry with respect to an interface extending in between, and the third and fourth dual port SRAM cells 10-3, 10-4 are in mirror symmetry with respect to an interface extending in between. Further, the first and third dual port SRAM cells 10-1, 10-3 are in mirror symmetry with respect to an interface extending in between, and the second and fourth dual port SRAM cells 10-2, 10-4 are in mirror symmetry with respect to an interface extending in between.

The lateral contacts placed along cell boundaries are shared by adjacent cells. Among these lateral contacts, the lateral contacts MD3, MD8 coupled to the reference voltage Vss and each placed at a central region of four abutted dual port SRAM cells (e.g., the dual port SRAM cells 10-1, 10-2, 10-3, 10-4) are shared by these four abutted dual port SRAM cells. As an example, the lateral contact MD8 shown in FIG. 5A is elongated across the interface between the dual port SRAM cells 10-1, 10-2 and the dual port SRAM cells 10-3, 10-4, to be shared by all of the dual port SRAM cells 10-1, 10-2, 10-3, 10-4. Although not depicted, the lateral contacts MD3 are respectively elongated and shared by four of the dual port SRAM cells 10 as well. Others of the lateral contacts shared by adjacent cells may include the lateral contacts MD1, MD4, MD5, MD6, MD9, MD10 as described with reference to FIG. 3.

Furthermore, the gate structures 316, 324 in each cell (as described with reference to FIG. 3) may extend across cell boundary, and can be shared by adjacent cells. Accordingly, the landing patterns M1a, M1e and the vias VG1, V1a, VG4, V1d (as described with reference to FIG. 3) connected to the gate structures 316, 324 and placed along cell boundary can be shared by adjacent cells as well.

In addition to the frontside layout patterns, backside layout patterns can be merged at cell boundaries. FIG. 5B is a schematic plan view showing layout of 4 adjacent dual port SRAM cells 10 at wafer backside, according to some embodiments of the present disclosure.

As shown in FIG. 5B, the backside power rails BM1b of the dual port SRAM cells 10-1, 10-2, 10-3, 10-4 can be merged into a single pattern. Although not depicted, the backside power rails BM1a at shared boundaries of four dual port SRAM cells 10 can be merged into a single pattern as well. As a result of the pattern merge, resistance across the backside power rails BM1a, BM1b can be greatly reduced.

In addition, the backside contacts BC1, BC2, BC3, BC4 can be shared by adjacent cells as well. Further, the backside power rails BM2 may respectively extend through and be shared by a row of the dual port SRAM cells 10.

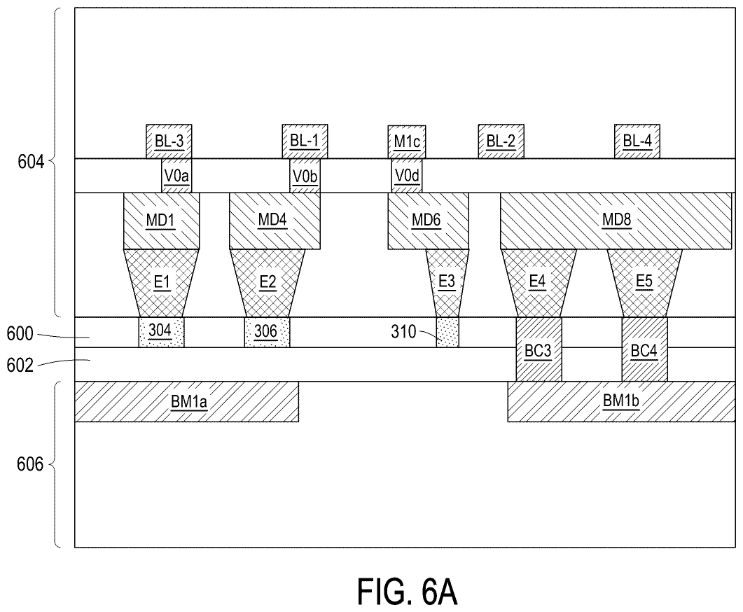

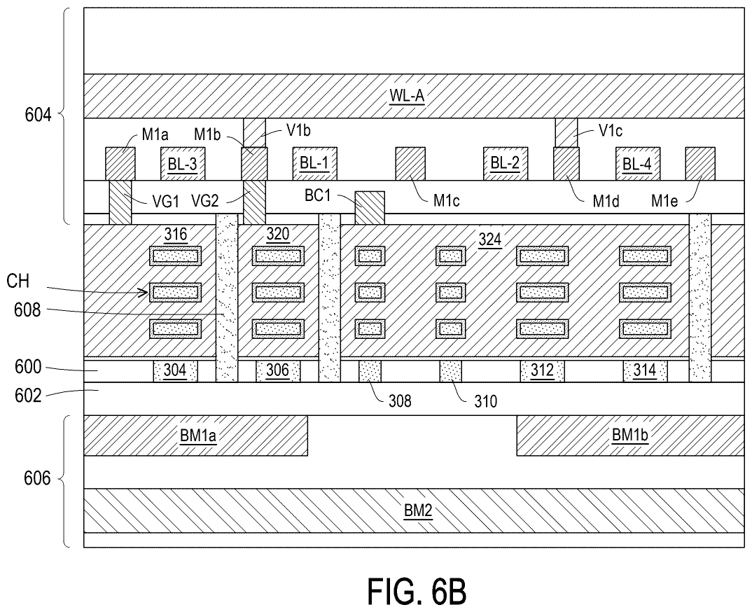

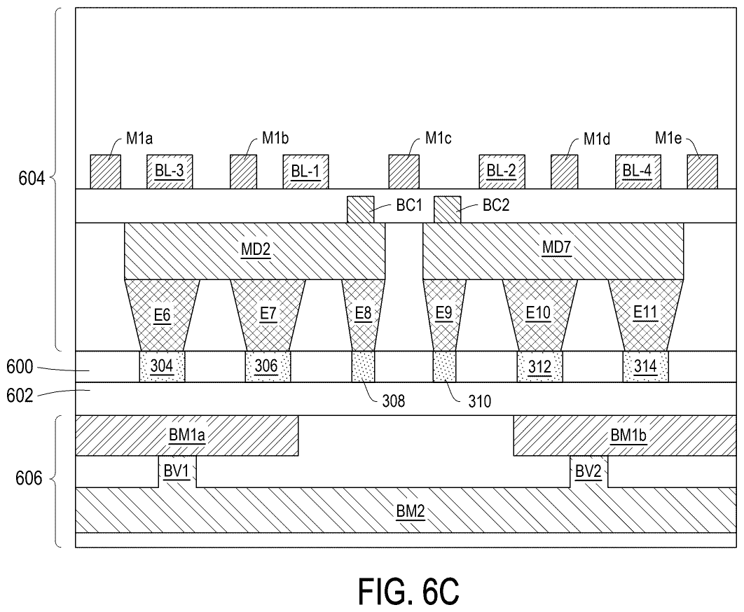

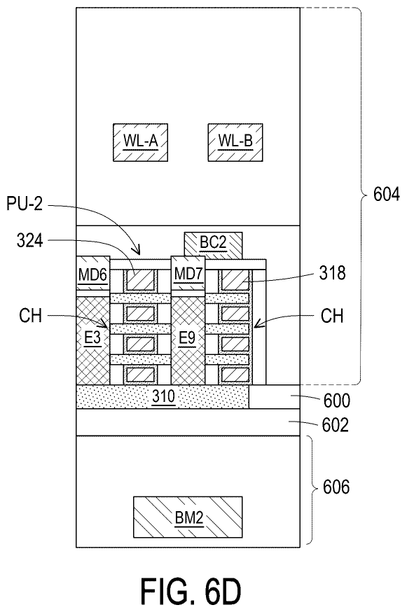

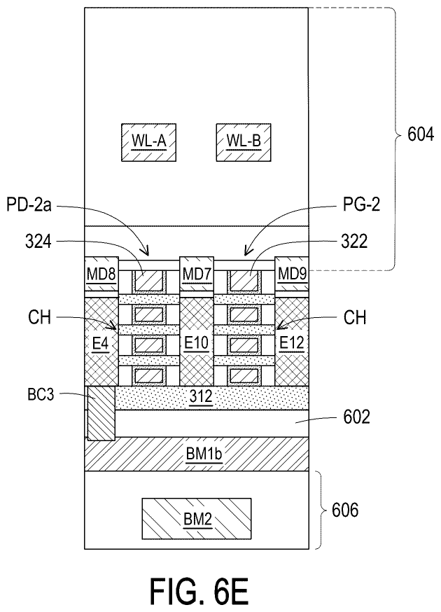

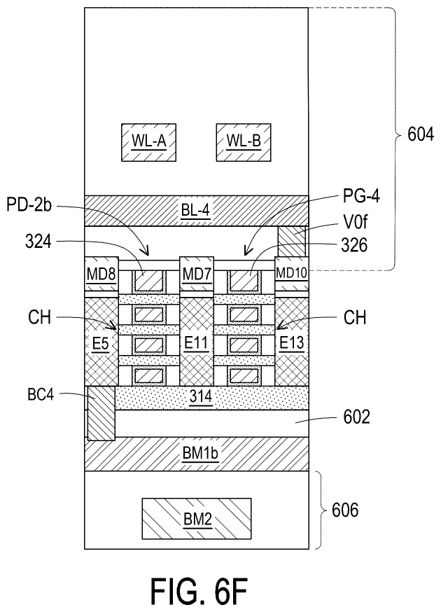

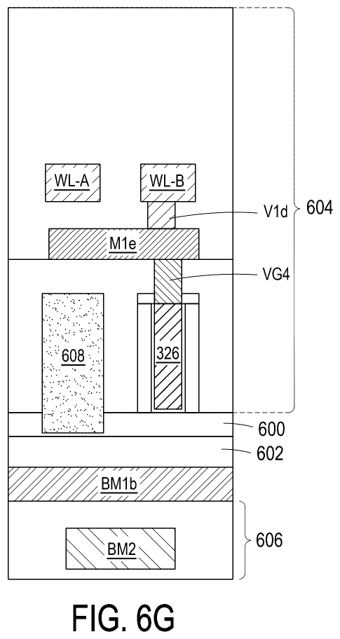

FIG. 6A through FIG. 6G are schematic cross-sectional views illustrating cross-sections along a few components in the dual port SRAM cell 10, according to some embodiments of the present disclosure.

Specifically, FIG. 6A depicts a cross-sectional view along the lateral contacts MD1, MD4, MD6, MD8, according to some embodiments of the present disclosure. The lateral contact MD1 is formed on a source/drain structure E1 provided as a source/drain terminal of the pass-gate transistor PG-3, and is connected to the overlying bit line BL-3 by the via V0a. The lateral contact MD4 is formed on a source/drain structure E2 provided as a source/drain terminal of the pass-gate transistor PG-1, and is connected to the overlying bit line BL-1 by the via V0b. The lateral contact MD6 is formed on a source/drain structure E3 provided as a source/drain terminal of the second pull-up transistor PU-2, and is connected to the overlying interconnection line M1c by the via V0d. Further, the lateral contact MD8 is formed on and bridges a source/drain structure E4 as a source/drain terminal of the second pull-down transistor PD-2a and a source/drain structure E5 as a source/drain terminal of the additional pull-down transistor PD-2b. The bit lines BL-2, BL-4 may overlap the lateral contact MD8, but may not be connected to the lateral contact MD8.

As shown in FIG. 6A, the source/drain structure E1 is formed on the active structure 304; the source/drain structure E2 is formed on the active structure 306; and the source/drain structure E3 is formed on the active structure 310. On the other hand, the source/drain structure E4 is formed on the active structure 312, which is not shown because it is locally removed for forming the backside contact BC3. Also, the source/drain structure E5 is formed on the active structure 314 not shown because it is locally removed for forming the backside contact BC4. The source/drain structures described in the present disclosure (including the source/drain structures E1 to E5 and the source/drain structures E6 to E13 to be described) may be provided as epitaxial structures, and can be doped with N-type or P-type, depends on the conductive type of the corresponding transistor.

The active structures 304, 306, 310, 312, 314 as well as the backside contacts BC3, BC4 are laterally surrounded by an isolation structure 600, such as a shallow trench isolation structure. A backside dielectric layer 602 is formed along a bottom side of the isolation structure 600, and the backside contacts BC3, BC4 extend through the backside dielectric layer 602 and the isolation structure 600 to reach the source/drain structures E4, E5. When the wafer backside faces upwardly, the backside power rails BM1a, BM1b are formed on the backside dielectric layer 602, and are connected to the source/drain structures E4, E5 through the backside contacts BC3, BC4.

The conductive features formed at a top side of the isolation structure 600 are embedded in a stack of frontside dielectric layers 604. In addition, the conductive features at a bottom side of the isolation structure 600 are embedded in a stack of backside dielectric layers including the backside dielectric layer 602 and one or more additional backside dielectric layer(s) 606. Although not shown in the cross-sectional views of FIG. 6A through FIG. 6G, the cap layer CL as described with reference to FIG. 4 is provided on top of the frontside dielectric layers 604, and the terminal layer TL described with reference to FIG. 4 is formed below the backside dielectric layer(s) 606.

FIG. 6B depicts a cross-sectional view along the word line WL-A, according to some embodiments of the present disclosure. In addition to the landing patterns M1a, M1b, M1c, M1d, the bit lines BL-1, BL-2, BL-3, BL-4 and the interconnection line M1c lying at a first metallization level, FIG. 6B further shows the word line WL-A and the connected vias V1b, V1c at a second metallization level, and also shows the gate vias VG1, VG2 as well as the butted contact BC1 at a ground metallization level. The vias V1b, V1c connect the word line WL-A to the landing patterns M1b, M1d. In addition, the gate via VG1 connects the landing pattern M1a to the gate structure 316, and the gate via V1b connects the landing pattern M1b to the gate structure 320. Further, the butted contact BC1 lands on the gate structure 324.

The gate structures 316, 320, 324 are laterally separated from one another, and isolation walls 608 are filled in between the gate structures 316, 320, 324. According to some embodiments, the active structures 304, 306, 310, 312, 314 each include channel structures CH stacked on a well region and vertically separated from one another. In these embodiments, the channel structures CH are wrapped all around by the intersecting gate structures. For example, the gate structure 316 wraps around the channel structures CH of the active structure 304; the gate structure 320 wraps around the channel structures CH of the active structure 306; and the gate structure 324 wraps around the channel structures CH of the active structures 308, 310, 312, 314.

FIG. 6B further shows that the backside power rail BM2 is formed further below the backside power rails BM1a, BM1b. As similar to the backside power rails BM1a, BM1b, the backside power rail BM2 is embedded in the backside dielectric layer(s) 606.

FIG. 6C depicts a cross-sectional view along the lateral contacts MD2, MD7, according to some embodiments of the present disclosure. The lateral contact MD2 is formed on and configured to bridge a source/drain structure E6 as the common source/drain terminal of the pass-gate transistor PG-3 and the additional pull-down transistor PD-1b, a source/drain structure E7 as the common source/drain terminal of the pass-gate transistor PG-1 and the first pull-down transistor PD-1a, and a source/drain structure E8 as a source/drain terminal of the first pull-up transistor PU-1. In addition, the lateral contact MD7 is formed on and configured to bridge a source/drain structure E9 as a source/drain terminal of the second pull-up transistor PU-2, a source/drain structure E10 as the common source/drain terminal of the pass-gate transistor PG-2 and the second pull-down transistor PD-2a, and a source/drain structure E11 as the common source/drain terminal of the pass-gate transistor PG-4 and the additional pull-down transistor PD-2b.

The butted contact BC1 lands on the lateral contact MD2, whereas the butted contact BC2 lands on the lateral contact MD7. The landing patterns M1a, M1b, M1c, M1d, the bit lines BL-1, BL-2, BL-3, BL-4 and the interconnection line M1c extend over the butted contacts BC1, BC2, but are not connected to the butted contacts BC1, BC2. Moreover, FIG. 6C further shows that the backside power rails BM1a, BM1b at wafer backside are connected to the backside power rail BM2 by the backside vias BV1, BV2.

FIG. 6D depicts a cross-sectional view along the active structure 310 and the butted contact BC2, according to some embodiments of the present disclosure. A first stack of the channel structures CH of the active structure 310 are wrapped around by the gate structure 324, at where the second pull-up transistor PU-2 is defined. The source/drain structures E3, E9 formed at opposite sides of the first stack of the channel structures CH are provided as the source/drain terminals of the second pull-up transistor PU-2, and the lateral contacts MD6, MD7 are formed on the source/drain structures E3, E9, respectively.

A second stack of the channel structures CH of the active structure 310 are intersected and wrapped around by the gate structure 318, which provides the gate terminals for the second pull-up transistor PU-2, the second pull-down transistor PD-2a and the additional pull-down transistor PD-2b. Further, the butted contact BC2 landing on the lateral contact MD7 and the gate structure 318 connects the source/drain structure E9 and the overlying lateral contact MD7 to the gate structure 318.

According to some embodiments, a dummy transistor is defined at where the gate structure 318 intersects the second stack of the channel structures CH of the active structure 310. Similarly, although not shown, another dummy transistor may be defined at where the gate structure 324 intersects the active structure 308.

FIG. 6E depicts a cross-sectional view along the active structure 312, according to some embodiments of the present disclosure. A first stack of the channel structures CH of the active structure 312 are wrapped around by the gate structure 324, at where the second pull-down transistor PD-2a is defined. The source/drain structure E4 formed at a side the first stack of the channel structures CH is provided as a source/drain terminal of the second pull-down transistor PD-2a, whereas the source/drain structure E10 formed at the other side of the first stack of the channel structures CH is provided as a common source/drain terminal of the second pull-down transistor PD-2a and the pass-gate transistor PG-2, which is defined at an intersection of the gate structure 322 and a second stack of the channel structures CH of the active structure 312. A source/drain structure E12 is formed at the other side of the second stack of the channel structures CH, and functioned as the other source/drain terminal of the pass-gate transistor PG-2.

To interconnect the second pull-down transistor PD-2a and the pass-gate transistor PG-2, the lateral contacts MD8, MD7, MD9 are formed on the source/drain structures E4, E10, E12, respectively. Further, the backside contact BC3 is formed through the backside dielectric layer 602 and well region of the active structure 312, to connect the backside power rail BM1b to the source/drain structure E4 as one of the source/drain terminals of the second pull-down transistor PD-2a.

FIG. 6F depicts a cross-sectional view along the active structure 314, according to some embodiments of the present disclosure. A first stack of the channel structures CH of the active structure 314 are wrapped around by the gate structure 324, at where the additional pull-down transistor PD-2b is defined. The source/drain structure E5 formed at a side the first stack of the channel structures CH is provided as a source/drain terminal of the additional pull-down transistor PD-2b, whereas the source/drain structure E11 formed at the other side of the first stack of the channel structures CH is provided as a common source/drain terminal of the additional pull-down transistor PD-2b and the pass-gate transistor PG-4, which is defined at an intersection of the gate structure 326 and a second stack of the channel structures CH of the active structure 314. A source/drain structure E13 is formed at the other side of the second stack of the channel structures CH, and functioned as the other source/drain terminal of the pass-gate transistor PG-4.

To interconnect the additional pull-down transistor PD-2b and the pass-gate transistor PG-4, the lateral contacts MD8, MD7, MD10 are formed on the source/drain structures E5, E11, E13, respectively. Further, the backside contact BC4 is formed through the backside dielectric layer 602 and well region of the active structure 314, to connect the backside power rail BM1b to the source/drain structure E5 as one of the source/drain terminals of the additional pull-down transistor PD-2b.

FIG. 6G depicts a cross-sectional view along the landing pattern M1e, according to some embodiments of the present disclosure. The landing pattern M1e is connected to the overlying word line WL-B by the via V1d, and is connected to the underlying gate structure 326 by the gate via VG4. According to some embodiments, one of the isolation walls 608 configured to cut off the gate structure 324 is overlapped with the landing pattern M1e. In these embodiments, the isolation wall 608 and the gate structure 326 are placed side-by-side and both overlapped with the overlying landing pattern M1e.

Since the dual port SRAM cell 10 is symmetrical, the plan views 300, 302 shown in FIG. 3 and the cross-sectional views shown in FIG. 6A through FIG. 6G in combination can reveal most of the structure of the dual port SRAM cell 10. As alternatives, several variations in terms of layout may be made to the dual port SRAM cell 10.

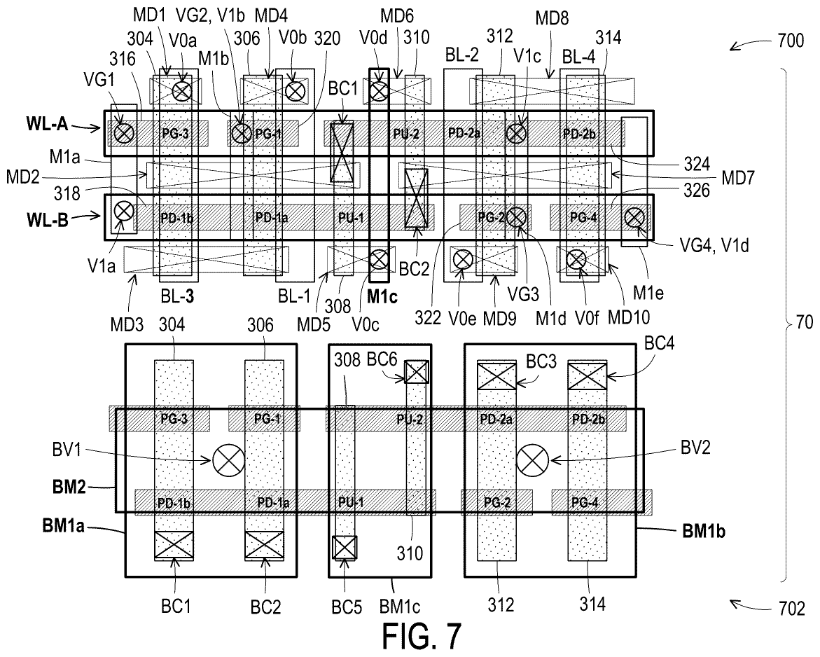

FIG. 7 provides schematic plan views 700, 702 showing layout design of a dual port SRAM cell 70 at wafer frontside and wafer backside, according to some embodiments of the present disclosure.

The dual port SRAM cell 70 is identical in terms of circuit design with the dual port SRAM 10 described above. In addition, the plan view 700 showing layout of the dual port SRAM cell 70 at wafer frontside is identical with the plan view 300 (in FIG. 3) showing layout of the dual port SRAM 10 at wafer frontside. Difference between the dual port SRAM cells 10, 70 lies in layout design at wafer backside.

As shown in the plan view 702 at wafer backside, the dual port SRAM cell 70 further includes backside contacts BC5, BC6 and a backside power rail BM1c. The backside contact BC5 extends through the active structure 308 from the wafer backside to establish contact with a source/drain structure, and is overlapped with the lateral contact MD5 in contact with the source/drain structure from a top side of the source/drain structure. On the other hand, the backside contact BC5 extends through the active structure 310 from the wafer backside to establish contact with a source/drain structure, and is overlapped with the lateral contact MD6 in contact with the source/drain structure from a top side of the source/drain structure.

The backside contacts BC5, BC6 are in contact with the backside power rail BM1c placed at the same height level with the backside power rails BM1a, BM1b and located in between the backside power rails BM1a, BM1b. Further, the backside power rail BM1c is coupled to the power supply voltage Vdd provided from the terminal layer TL as described with reference to FIG. 4.

Based on such configuration, the interconnection line M1c connected to the lateral contacts MD5, MD6 can be coupled to the power supply voltage Vdd through the backside contacts BC5, BC6 and the backside power rail BM1c. In addition, the interconnection line M1c is connected in parallel with the backside power rail BM1c. Accordingly, an equivalent resistance of the interconnection line M1c and the backside power rail BM1c connected in parallel would be lower than a resistance of the interconnection line M1c itself. Thereby, by further disposing the backside contacts BC5, BC6 and the backside power rail BM1c, resistance along the paths for providing the power supply voltage Vdd can be lowered. Furthermore, even if one of the backside contacts BC5, BC6 fails to connect the corresponding source/drain terminal to the backside power rail BM1c, such source/drain terminal can be connected to the backside power rail BM1c via the lateral contacts MD5, MD6, the interconnection line M1c and the other backside contact BC5/BC6. Accordingly, tolerance of overlay between the backside contacts BC5, BC6 and the active structures 308, 310 are improved. According to some embodiments, the interconnection line M1c is not further coupled to the power supply voltage Vdd via through substrate via(s).

As compared to the frontside of the semiconductor substrate, the backside of the semiconductor substrate is much less crowded with wirings, and the backside power rail BM1c can widely span to reduce sheet resistance, as similar to the backside power rails BM1a BM1b. In some embodiments, the backside power rail BM1c is overlapped with the N well where the active structures 308, 310 sit, and the active structures 308, 310 may be entirely overlapped with the backside power rail BM1c. In addition, a width of the backside power rail BM1c along the direction which the gate structures 316, 318, 320, 322, 324, 326 extend may be greater than a total width of the active structures 308, 310 along the same direction, and the backside power rail BM1c may extend along the N well and the active structures 308, 310.

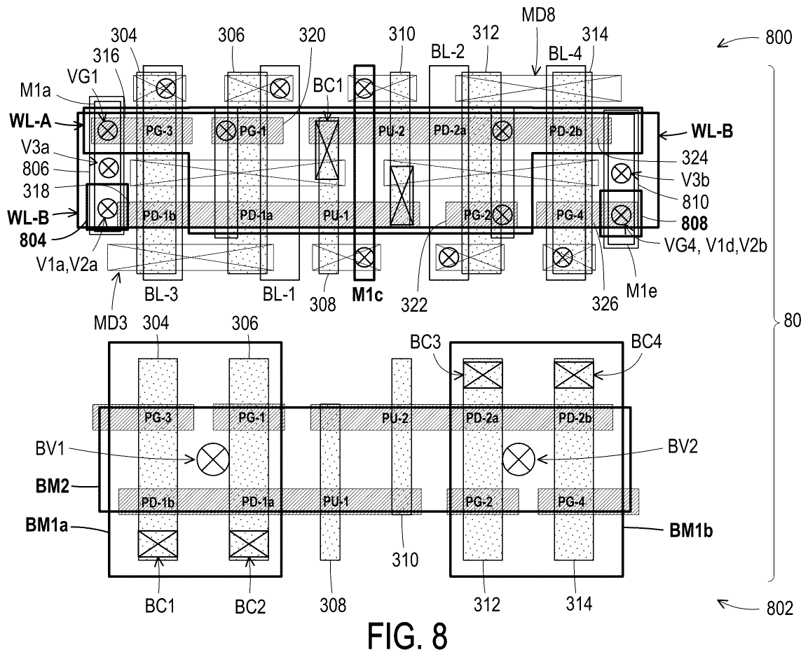

In addition to variation to the backside layout, additional variation can be made to the frontside layout. FIG. 8 provides schematic plan views 800, 802 showing layout design of a dual port SRAM cell 80 at wafer frontside and wafer backside, according to some embodiments of the present disclosure.

The dual port SRAM cell 80 is identical in terms of circuit design with the dual port SRAM 10 described above. In addition, the plan view 802 showing layout of the dual port SRAM cell 80 at wafer backside is identical with the plan view 302 (in FIG. 3) showing layout of the dual port SRAM 10 at wafer backside. Difference between the dual port SRAM cells 10, 80 lies in layout design at wafer frontside.

As shown in the plan view 800 at wafer frontside, while the gate structure 320 providing the gate terminal for the pass-gate transistor PG-1 and the gate structure 322 providing the gate terminal for the pass-gate transistor PG-2 are connected to the word line WL-A at the second metallization tier M2 (as described with reference to FIG. 4), the gate structure 316 providing the gate terminal for the pass-gate transistor PG-3 and the gate structure 326 providing the gate terminal for the pass-gate transistor PG-4 are connected to the word line WL-B at higher metallization tier, such as a fourth metallization tier above the second metallization tier.

Specifically, the gate structure 316 is connected to the landing pattern M1a by the gate via VG1, and the landing pattern M1a is connected to another landing pattern 804 by the via V1a. The landing pattern 804 is located at the same metallization tier as the word line WL-A (i.e., the second metallization tier M2). Further, the additional landing pattern 804 is connected to yet another landing pattern 806 at the next metallization tier (i.e., the third metallization tier) by a via V2a. Eventually, the landing pattern 806 is connected to the word line WL-B at the fourth or higher metallization tier. In some embodiments, the landing pattern 806 is connected to the word line WL-B at the fourth metallization tier by a via V3a.

Similarly, the gate structure 326 is connected to the landing pattern M1e by the gate via VG4, and the landing pattern M1e is connected to another landing pattern 808 by the via V1d. The landing pattern 808 is located at the same metallization tier as the word line WL-A (i.e., the second metallization tier M2). Further, the additional landing pattern 808 is connected to yet another landing pattern 810 at the next metallization tier (i.e., the third metallization tier) by a via V2b. Eventually, the landing pattern 810 is connected to the word line WL-B at the fourth or higher metallization tier. In some embodiments, the landing pattern 810 is connected to the word line WL-B at the fourth metallization tier by a via V3b.

As the word line WL-A and the word line WL-B are deployed at different height levels, line width and line pitch of the word lines WL-A, WL-B can be increased for reducing resistance along the word lines WL-A, WL-B. In some embodiments, each of the word lines WL-A, WL-B spans across a spacing between the gate structures 316, 320, 324 and the gate structures 318, 322, 326 along a width direction of the word lines WL-A, WL-B, and the lateral contacts MD2, MD7 placed along the spacing are overlapped with the word lines WL-A, WL-B. Moreover, in some embodiments, the word line WL-A is overlapped with the word line WL-B.

As described, in some embodiments, the landing patterns 804, 808 at the same height as the word line WL-A are required for routing the gate structures 316, 326 to the word line WL-B. In these embodiments, the word line WL-A has to extend around the landing patterns 804, 808, to prevent from being in contact with and/or capacitively coupled to the landing patterns 804, 808. When the landing pattern 804 overlaps the gate structure 318 and the landing pattern 808 overlaps the gate structure 326, the word line WL-A extending along the gate structures 316, 318, 32, 322, 324, 326 is locally narrowed in corresponding to the landing patterns 804, 808, such that a section of the gate structure 318 covered by the landing pattern 804 and the gate pattern 326 would not be overlapped with the word line WL-A. On the other hand, the gate structures 316, 320, 322, 324 may be entirely covered by the word line WL-A, and rest portions of the gate structure 318 are covered by the word line WL-A as well. Further, since the word line WL-B runs above all of the described landing patterns, the word line WL-B does not have to be locally narrowed. Rather, in some embodiments, the word line WL-B may overlap all of the gate structures 316, 318, 320, 322, 324, 326.

Although not shown, the backside contacts BC5, BC6 described with reference to FIG. 7 may be further added to the dual port SRAM cell 80, as a further alternative.

As above, a dual port SRAM with power rails formed at wafer backside is provided. Since the power rails are disposed at less crowded wafer backside (as compared to wafer frontside), the power rails can be designed with greater footprint area, and resistance along the power supply paths can be significant reduced. Also, routing area at the wafer frontside can be released, such that word lines and bit lines at the wafer frontside can be formed with greater line width and line pitch. In addition, as the backside power rails are rather close to electrical connectors also formed at wafer backside, power source can be supplied to the backside power rails with minimum voltage drop. Further, by using frontside lateral contacts (i.e., the lateral contacts MD3, MD8) to bridge source/drain terminals coupled to the same backside power rail, these frontside lateral contacts are connected in parallel to the corresponding backside power rail. Based on such configuration, an equivalent resistance of the lateral contacts and the backside power rail connected in parallel is lowered, as compared to the resistance of the backside power rail itself. Moreover, if one of the connected source/drain terminals fails to be connected to the backside power rail by a backside contact in between, such source/drain terminal can still be connected to the backside power rail through the frontside lateral contact and the other backside contact. Therefore, process window for laying the backside contacts can be widened.

In an aspect of the present disclosure, an integrated circuit is provided. The integrated circuit comprises memory cells, respectively comprising: an inverter, formed on a frontside of a semiconductor substrate, and comprising two pull-down transistors connected in parallel and a pull-up transistor connected to the pull-down transistors; a lateral contact, formed over the inverter at the frontside of the semiconductor substrate, and laterally extending to land on a source/drain terminal of one of the pull-down transistors and a source/drain terminal of the other of the pull-down transistors; and a power rail, extending at a backside of the semiconductor substrate and coupled to a reference voltage, wherein the source/drain terminals of the pull-down transistors bridged by the lateral contact are further connected to the power rail.

In another aspect of the present disclosure, an integrated circuit is provided. The integrated circuit comprises an array of cells, respectively comprising: an inverter, formed on a frontside of a semiconductor substrate, and comprising two first-type transistors connected in parallel and a second-type transistor connected to the first-type transistors; a contact, formed over the inverter at the frontside of the semiconductor substrate, and laterally extending to land on a source/drain terminal of one of the first-type transistors and a source/drain terminal of the other of the first-type transistors; and a metal line, extending at a backside of the semiconductor substrate and coupled to a voltage source, wherein the source/drain terminals of the first-type transistors bridged by the contact are further connected to the metal line.

In yet another aspect of the present disclosure, an integrated circuit is provided. The integrated circuit comprises: a latch circuit, formed on a frontside of a semiconductor substrate, and having a first storage node and a second storage node, wherein the first storage node is switchably coupled to a reference voltage through two first pull-down transistors connected in parallel, and the second storage node is switchably coupled to the reference voltage through two second pull-down transistors connected in parallel; a first lateral contact, formed at the frontside of the semiconductor substrate, and laterally extending to land on a source/drain terminal of one of the first pull-down transistors and a source/drain terminal of the other of the first pull-down transistors; a first power rail, extending at a backside of the semiconductor substrate, wherein the source/drain terminals of the first pull-down transistors bridged by the first lateral contact are further connected to the first power rail; a second lateral contact, formed at the frontside of the semiconductor substrate, and laterally extending to land on a source/drain terminal of one of the second pull-down transistors and a source/drain terminal of the other of the second pull-down transistors; and a second power rail, extending at the backside of the semiconductor substrate, wherein the source/drain terminals of the second pull-down transistors bridged by the second lateral contact are further connected to the second power rail.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
an array of cells, respectively comprising:
an inverter, formed on a frontside of a semiconductor substrate, and comprising two first-type transistors connected in parallel and a second-type transistor connected to the first-type transistors;
a contact, formed over the inverter at the frontside of the semiconductor substrate, and laterally extending to land on a source/drain terminal of one of the first-type transistors and a source/drain terminal of the other of the first-type transistors; and
a metal line, extending at a backside of the semiconductor substrate and coupled to a voltage source, wherein the source/drain terminals of the first-type transistors bridged by the contact are further connected to the metal line.

2. The integrated circuit according to claim 1, wherein the contact at the frontside of the semiconductor substrate is connected in parallel with the metal line at the backside of the semiconductor substrate.

3. The integrated circuit according to claim 1, wherein the voltage source is only provided from electrical connectors in a terminal layer as an outermost layer at the backside of the semiconductor substrate.

4. The integrated circuit according to claim 3, wherein the metal line is connected to the electrical connectors through one or more additional metal lines formed over the metal line at the backside of the semiconductor substrate.

5. The integrated circuit according to claim 1, wherein the source/drain terminals of the first-type transistors are provided by epitaxial structures, and the contact laterally extends and directly lands on the epitaxial structures.

6. The integrated circuit according to claim 5, further comprising:
a first backside contact and a second backside contact, formed through the semiconductor substrate from the backside of the semiconductor substrate, and connecting the epitaxial structures to the metal line.

7. The integrated circuit according to claim 1, wherein the contact extends across a shared boundary of two adjacent ones of the cells, and is shared by the two adjacent ones of the cells.

8. The integrated circuit according to claim 1, wherein the metal line spans across a shared boundary of two adjacent ones of the cells, and is shared by the two adjacent ones of the cells.

9. The integrated circuit according to claim 1, wherein an outermost layer at the frontside of the semiconductor substrate is provided by a cap layer, without any electrical connector.

10. The integrated circuit according to claim 9, wherein the cap layer is a semiconductor layer.

11. An integrated circuit, comprising:
memory cells, respectively comprising:
a first inverter, formed on a frontside of a semiconductor substrate, and comprising two first pull-down transistors connected in parallel and a first pull-up transistor connected to the first pull-down transistors;
a second inverter, formed on the frontside of the semiconductor substrate, and comprising two second pull-down transistors connected in parallel and a second pull-up transistor connected to the pull-down transistors; and
a first power rail, formed over the first and second invertors at the frontside of the semiconductor substrate, and coupled to a power supply voltage, wherein a source/drain terminal of the first pull-up transistor and a source/drain terminal of the second pull-up transistor are bridged by the first power rail, and the power supply voltage is provided solely from a backside of the semiconductor substrate.

12. The integrated circuit according to claim 11, wherein the first power rail is coupled to the power supply voltage via a through substrate via extending through the semiconductor substrate.

13. The integrated circuit according to claim 11, further comprising:
a second power rail, extending at the backside of the semiconductor substrate and coupled to the power supply voltage, wherein the source/drain terminals of the first and second pull-up transistors bridged by the first power rail are further connected to the second power rail.

14. The integrated circuit according to claim 13, further comprising:
a first backside contact and a second backside contact, formed through the semiconductor substrate from the backside of the semiconductor substrate, and connecting the source/drain terminals of the first and second pull-up transistors to the second power rail.

15. The integrated circuit according to claim 13, wherein the first power rail at the frontside of the semiconductor substrate is connected in parallel with the second power rail at the backside of the semiconductor substrate.

16. An integrated circuit, comprising:
a latch circuit, formed on a frontside of a semiconductor substrate, and having a first storage node and a second storage node, wherein the first storage node is switchably coupled to a reference voltage through two first pull-down transistors connected in parallel, and the second storage node is switchably coupled to the reference voltage through two second pull-down transistors connected in parallel;
a first lateral contact, formed at the frontside of the semiconductor substrate, and laterally extending to land on a source/drain terminal of one of the first pull-down transistors and a source/drain terminal of the other of the first pull-down transistors;
a first power rail, extending at a backside of the semiconductor substrate, wherein the source/drain terminals of the first pull-down transistors bridged by the first lateral contact are further connected to the first power rail;
a second lateral contact, formed at the frontside of the semiconductor substrate, and laterally extending to land on a source/drain terminal of one of the second pull-down transistors and a source/drain terminal of the other of the second pull-down transistors; and
a second power rail, extending at the backside of the semiconductor substrate, wherein the source/drain terminals of the second pull-down transistors bridged by the second lateral contact are further connected to the second power rail.

17. The integrated circuit according to claim 16, further comprising:
a first pass-gate transistor and a second pass-gate transistor, coupled to and configured to control a first port to the first and second storage nodes, respectively;
a third pass-gate transistor and a fourth pass-gate transistor, coupled to and configured to control a second port to the first and second storage nodes, respectively.

18. The integrated circuit according to claim 17, wherein a first word line connected to gate terminals of the first and second pass-gate transistors and a second word line connected to gate terminals of the third and fourth pass-gate transistors are formed at the same height level at the frontside of the semiconductor substrate.

19. The integrated circuit according to claim 17, wherein a first word line connected to gate terminals of the first and second pass-gate transistors and a second word line connected to gate terminals of the third and fourth pass-gate transistors are formed at different height levels at the frontside of the semiconductor substrate.

20. The integrated circuit according to claim 19, wherein the first and second word lines are overlapped with each other.
